(19) United States
(12) Patent Application Publication
(10) Pub. No.: US 2016/0380153 A1
(43) Pub. Date: Dec. 29, 2016

(54) SUBSTRATE, METHOD OF PREPARING THE SAME, AND LIGHT-EMITTING DIODE USING THE SUBSTRATE

(71) Applicant: GWANGJU INSTITUTE OF SCIENCE AND TECHNOLOGY, Gwangju (KR)

(72) Inventors: Dong-Seon LEE, Gwangju (KR); Duk-Jo Kong, Gwangju (KR)

(21) Appl. No.: 15/191,862

(22) Filed: Jun. 24, 2016

(30) Foreign Application Priority Data
Jun. 25, 2015 (KR) 10-2015-0090640
Jan. 15, 2016 (KR) 10-2016-0005355

(51) Int. Cl. H01L 33/32; H01L 33/00; H01L 33/24; H01L 33/08

(52) U.S. Cl. CPC H01L 33/32; H01L 33/08; H01L 33/0075; H01L 33/24

(57) ABSTRACT

The present invention relates to a gallium nitride substrate, a method of preparing the gallium nitride substrate, and a double-sided light-emitting diode using the gallium nitride substrate. The gallium nitride substrate has a first face having a Ga-polar face and a second face having an N-polar face. Protrusions with semi-polar surfaces are formed on the second face. A light-emitting body may be formed on the first face, and a separate light-emitting body may be formed through the surfaces of the protrusions.

### BACKGROUND

1. Technical Field

The present invention relates to a substrate, a method of preparing the substrate, and a light-emitting diode prepared by using the substrate, and more particularly, to a gallium nitride substrate and a light-emitting diode having a multi-junction structure which is formed on the gallium nitride substrate.

2. Description of the Related Art

A light-emitting diode is constituted with a compound semiconductor, and most of compound semiconductors are formed by a metal organic chemical vapor deposition (MOCVD) process. The MOCVD process commonly used in the art uses a material, in which a metal and an organic material are combined, as a metal precursor. Also, the compound semiconductor is preferably constituted with a monocrystal, and high brightness and excellent thermal stability may be secured by formation of the monocrystal. In particular, when defects of the crystalline state occur in an active layer performing a light-emitting operation, unstable brightness may be generated, brightness may deteriorate at a high operation current, or excessive heat may be generated. Therefore, forming the compound semiconductor in a monocrystal form is a vital issue in a preparation process of a light-emitting diode.

Further, even when the MOVCD process is used, a compound semiconductor layer thus formed is influenced by the crystallinity and crystal orientation of a stack structure located under the layer. For example, when an active layer having a gallium nitride as a ground material is formed on an n-type semiconductor layer formed of a gallium nitride, dislocation or point defects existing in the n-type semiconductor layer may result in dislocation or defects in the active layer that is formed on the n-type semiconductor layer.

Also, the compound semiconductor layer is affected by crystal orientation and a lattice constant of a substrate, which becomes a base of crystal growth. That is, the substrate is suitable when it has the same crystal structure with a crystal structure of the compound semiconductor layer, and the compound semiconductor layer with excellent quality may be formed when a difference between lattice constants is small.

The substrate that may be used in preparation of a gallium nitride-based light-emitting diode may include sapphire, silicon, or gallium nitride.

Sapphire is a substrate that is most commonly used in the preparation process of a light-emitting diode. The crystalline structure of sapphire has a hexagonal system, which is advantageous in terms of growth of a gallium nitride-based light-emitting diode. Also, when sapphire is used, a preparation process for the substrate is relatively simple, and good measure of compatibility for relatively low price may be secured. However, due to characteristics of a semiconductor, heat may not be easily released, and defects of a crystalline structure which may be caused by a difference between lattice constants of gallium nitride and sapphire.

Silicon has been generally used as a semiconductor substrate and has excellent heat radiating characteristics compared to those of sapphire. However, the crystalline structure of silicon has a face-centered cubic system, which is different from the crystalline structure of a gallium nitride. Thus, formation of a gallium nitride monocrystal on a silicon substrate may be technically difficult, and multiple buffer layers are needed.

Since a gallium nitride substrate is a semiconductor material which has excellent heat radiating characteristics due to its high heat conductivity, formation of a gallium nitride light-emitting layer on the gallium nitride substrate would be particularly easy, and a light-emitting diode of high quality may be manufactured. However, the substrate may not be manufactured by using a common substrate preparation process. Also, a manufacturing cost of the gallium nitride substrate may be high, which may restrict application of the substrate in the industry.

Accordingly, studies on techniques to easily prepare a gallium nitride substrate and to manufacture a light-emitting diode by using a MOCVD process have been conducted in the art, and the techniques are expected to produce significant industrial ripple effects.

### SUMMARY

It is an aspect of the present invention to provide a gallium nitride substrate.

It is another aspect of the present invention to provide a method of preparing a gallium nitride substrate.

Also, it is another aspect of the present invention to provide a double-sided light-emitting diode by using the gallium nitride substrate that may be obtained by achievement of an aspect of the present invention.

The present invention is not limited to the above aspect and other aspects of the present invention will be clearly understood by those skilled in the art from the following description.

In accordance with one aspect of the present invention, a gallium nitride substrate includes a first face that has a Ga-polar face having gallium atoms arranged on a surface thereof; a second face that faces the first face and has an N-polar face having nitrogen atoms arranged on a surface thereof; and protrusions that are formed on the second face and have a protruding surface, which is a semi-polar surface.

In accordance with another aspect of the present invention, a method of preparing a gallium nitride substrate includes forming mask patterns and gallium nitride rods that reclaim gaps between the mask patterns on a substrate for growth; covering the mask patterns by having the gallium nitride rods as nuclei for growth to form a gallium nitride layer; removing the covered mask patterns; and etching the gallium nitride rods by providing an etchant to etched holes formed by the removing of the mask patterns to form protrusions having some of the gallium nitride rods remained on the gallium nitride layer.

In accordance with another aspect of the present invention, a double-sided light-emitting diode includes a gallium nitride substrate formed of a gallium nitride material; a first light-emitting body that has been grown in a first direction from the gallium nitride substrate; and a second light-emitting body that has been grown in a second direction, which is opposite to the first direction, from the gallium nitride substrate.

### BRIEF DESCRIPTION OF DRAWINGS

FIG. 1 is a cross-sectional view of a gallium nitride substrate according to an embodiment of the present invention.

FIG. 2 is a schematic view of a crystalline structure of a gallium nitride according to an embodiment of the present invention.

FIG. 3 is a cross-sectional view to illustrate a method of preparing the gallium nitride substrate according to an embodiment of the present invention.

FIG. 4 is a cross-sectional view to illustrate a method of preparing the gallium nitride substrate according to an embodiment of the present invention.

FIG. 5 is a cross-sectional view to illustrate a method of preparing the gallium nitride substrate according to an embodiment of the present invention.

FIG. 6 is a cross-sectional view to illustrate a method of preparing the gallium nitride substrate according to an embodiment of the present invention.

FIG. 7 is an image that shows a gallium nitride layer formed on a gallium nitride rod according to an embodiment of the present invention.

FIG. 8 is an image that shows the gallium nitride substrate according to an embodiment of the present invention.

FIG. 9 is a cross-sectional view of a double-sided light-emitting diode according to another embodiment of the present invention.

### DETAILED DESCRIPTION

As the present invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope are encompassed in the present invention. In the description, certain detailed explanations of the related art are omitted when it is deemed that they may unnecessarily obscure the essence of the present invention. Like reference numerals in the drawings denote like elements.

Unless defined otherwise in the detailed description, all the terms including technical and scientific terms have the same meaning as meanings generally understood by those skilled in the art to which the present invention pertains. Generally used terms such as terms defined in a dictionary should be interpreted as the same meanings as meanings within a context of the related art and should not be interpreted as ideally or excessively formal meanings unless clearly defined in the present specification.

Hereinafter, embodiments of the present invention will be described in detail with reference to the accompanying drawings.

### First Embodiment

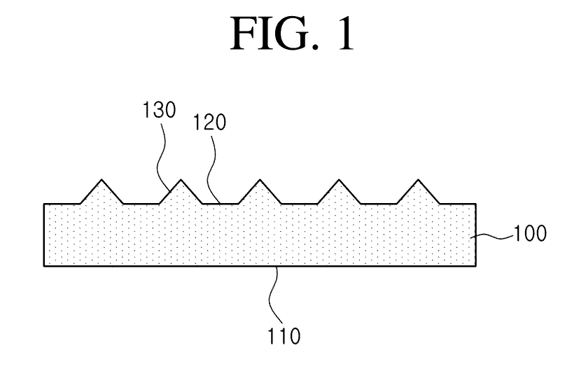

FIG. 1 is a cross-sectional view of a gallium nitride substrate 100 according to an embodiment of the present invention.

Referring to FIG. 1, a first face 110 of the gallium nitride substrate 100 is a Ga-polar face, and a second face 120 of the gallium nitride substrate 100 is an N-polar face. Also, protrusions 130 are formed on the second face 120, and the protrusions 130 form a semi-polar face.

In general, a hexagonal crystalline structure is represented by facial indices (a1, a2,−(a1+a2), c). Also, a face perpendicular to a c-axis is referred to as a polar face; a face parallel to a c-axis is referred to as a nonpolar face; and a face that is neither perpendicular nor parallel to a c-axis is referred to as a semi-polar face.

In a crystalline structure of a gallium nitride, the Ga-polar face refers to a polar face, where gallium atoms are present; and the N-polar face refers to a polar face, where nitrogen atoms are present. Also, the semi-polar face is not a (0001) face of the crystalline structure of a gallium nitride and refers to a face that is leaned at an angle according to a hexagonal structure. For example, (11-22), (11-2-3), (10-13), (11-20), (1-100), (-1-123), or (10-12) may correspond to the semi-polar faces.

Also, the protrusions 130 may be regularly arranged with a constant interval distance between each other.

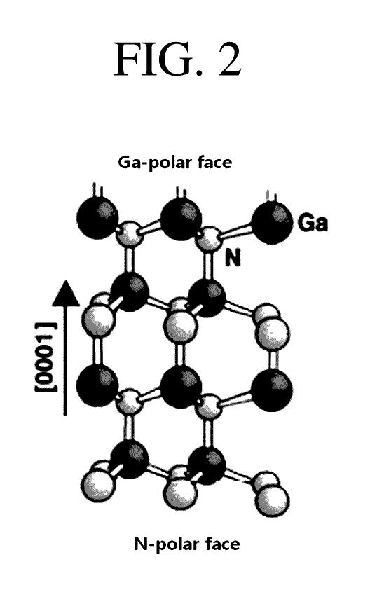

FIG. 2 is a schematic view of a crystalline structure of a gallium nitride according to an embodiment of the present invention.

Referring to FIG. 2, a Ga-polar face, where gallium atoms are present, faces up in the hexagonal crystalline structure of a gallium nitride. Also, an N-polar face, where nitrogen atoms are present, faces down in the crystalline structure. When a section surface is cut at an angle from the crystalline structure shown in FIG. 2 and thus a face where nitrogen and gallium atoms are both present at the same time is formed, the section surface corresponds to a semi-polar surface. Examples of the semi-polar face may include (11-22), (11-2-3), (10-13), (11-20), (1-100), (-1-123), or (10-12).

The N-polar face has a surface energy that is lower than that of the Ga-polar face, and thus the N-polar face maintains relatively stable state, which results in slow growth of crystals via a reaction compared to growth of crystals from the Ga-polar face. Also, the semi-polar face is chemically unstable compared to the N-polar face and the Ga-polar face and thus may be relatively fast etched by an etchant from the outside.

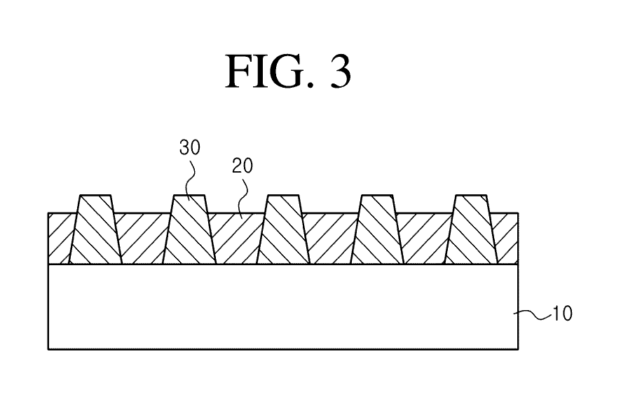

FIGS. 3 to 6 are cross-sectional views to illustrate a method of preparing the gallium nitride substrate according to an embodiment of the present invention.

Referring to FIG. 3, mask patterns 20 are formed on a substrate 10 for growth, and gallium nitride rods 30 are formed in gaps between the mask patterns 20.

The substrate 10 for growth may be formed of a material such as sapphire or gallium nitride. Also, the substrate 10 for growth may be a physically independent substrate or a particular membrane that is formed on another substrate.

The mask patterns 20 may be formed of a silicon oxide or a silicon nitride, and any material that may maintain its shape at a MOCVD process temperature may be used to form the mask patterns 20. The mask patterns 20 are formed on the substrate 10 for growth. The mask patterns 20 may be prepared by forming a mask layer on the substrate 10 for growth, forming a photoresist pattern on the mask layer through a general photolithography process, and then performing an etching process by using the photoresist pattern as an etching mask. Through the etching process performed on the mask layer, a width of an upper part of each of the mask patterns 20 may be greater than a width of a lower part. That is, the mask patterns 20 may be formed by under-cut type of etching.

The gallium nitride rods 30 may be formed in gaps between the mask patterns 20. The gallium nitride rods 30 may reclaim the gaps between the mask patterns 20. Formation of the gallium nitride rods 30 may be performed by a general MOCVD process using the substrate 10 for growth as a seed.

Further, the gallium nitride rods 30 and the mask patterns 20 may be formed by using another process. For example, first, a gallium nitride layer may be formed based on the substrate 10 for growth. By selective-etching of the gallium nitride layer thus formed, a part of the substrate 10 for growth is exposed, and the gallium nitride rods 30 are formed. Thereafter, gaps between the gallium nitride rods 30 may be reclaimed with a silicon nitride or a silicon oxide to form the mask patterns 20.

Also, a side surface of the gallium nitride rods 30 formed by a MOCVD process or by performing an etching process may be a semi-polar surface.

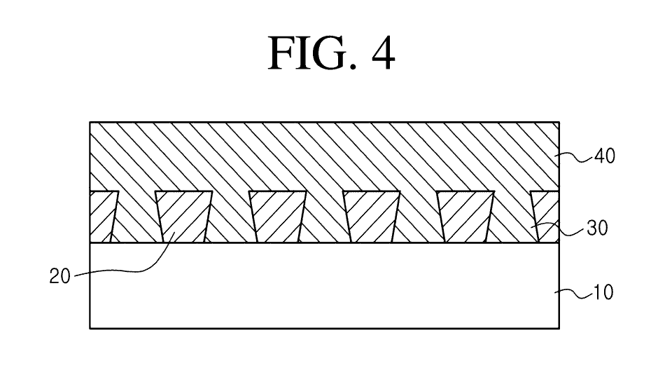

Referring to FIG. 4, secondary growth may be performed by using gallium nitride rods thus formed as nuclei of growth. An epitaxial lateral over-growth (ELOG) method, which results better horizontal growth than vertical growth, may be used in the secondary growth. Also, a hydride vapor phase epitaxy (HYPE) method that is preferable for epitaxial layer formation may be used.

In particular, the HYPE method is preferable in formation of an epitaxial layer of a gallium nitride. When the HYPE method is used, a growth temperature may be set in a range of 800° C. to 1100° C., and a ratio between a NH3 gas and a GaCl gas supplied to a HYPE reactor may be set in a range of 1:1 to 10:1.

In this regard, a gallium nitride layer 40 that covers the mask patterns 20 may be formed on the gallium nitride rods 30. The uppermost layer of the gallium nitride layer 40 may be a Ga-polar face having gallium atoms on a surface thereof. Also, the lowermost part of the gallium nitride layer 40 that meets an upper surface of the mask patterns 20 may be an N-polar face having nitrogen atoms on a surface thereof according to an epitaxial growth mechanism.

Also, according to the preparation method, the secondary growth may be integrated with growth of the gallium nitride rods 30 in FIG. 3.

That is, the gallium nitride rods 30 may be formed based on the substrate 10 for growth through the gaps between the mask patterns 20, and the gallium nitride layer 40 that covers the mask patterns 20 may be formed on the gallium nitride rods through consecutive processes.

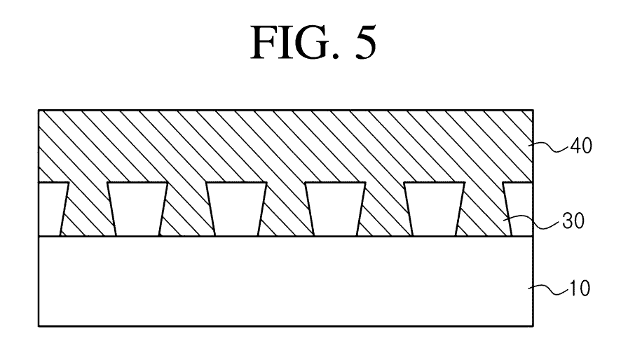

Referring to FIG. 5, a mask pattern is removed by first etching. An etchant used in the first etching may be a HF solution. However, the etchant selected for an embodiment of FIG. 5 may be any material that has etching selectivity between the mask pattern and a gallium nitride. That is, a solution that may selectively remove a mask pattern may be used as an etchant. Through the first etching, the mask pattern is removed, and the gallium nitride rods 30 and the gallium nitride layer 40 remain on the substrate 10 for growth. Also, etching holes defined by the substrate 10 for growth, the gallium nitride rods 30, and the gallium nitride layer 40 are formed by the removed mask pattern.

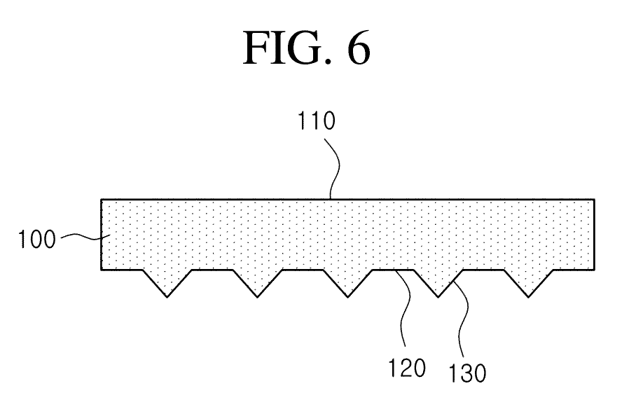

Referring to FIG. 6, a substrate 100 is formed through second etching. The second etching may be achieved by supplying an etchant through the etching holes of FIG. 5. The etchant is preferably KOH, and a concentration of KOH may range from 1 M to 5 M. When a concentration of KOH is lower than 1 M, etching may not be smoothly performed. Also, when a concentration of KOH is higher than 5 M, a side effect of the etching being performed up to a gallium nitride layer due to the fast etching may occur. Also, an etching temperature of KOH is preferably in a range of 60° C. to 120° C. When an etching temperature is lower than 60° C., the etching may not occur smoothly due to the low temperature, and when an etching temperature is higher than 120° C., the etching temperature is close to a boiling point of the KOH solution, and thus controlling a concentration and repeatability of a process may deteriorate.

The second etching is intensified for the gallium nitride rods. The etching holes formed in an embodiment of FIG. 5 are defined by the substrate 10 for growth, the gallium nitride rods 30, and the gallium nitride layer 40. Also, a surface of the gallium nitride layer 40 exposed to the etching holes is an N-polar face and thus is chemically stable. Also, when the substrate 10 for growth is formed of a gallium nitride material, a surface of the substrate 10 for growth exposed to the etching holes is a Ga-polar face and thus is chemically unstable compared to that of the N-polar face but has a corner portion and a chemically stable state compared to that of the gallium nitride rods 30 having an exposed semi-polar face.

The gallium nitride rods 30 have a semi-polar face as a lateral surface thereof. Also, a face meeting the gallium nitride layer 40 has a corner portion that is chemically most unstable. The second etching intensively occurs at the corner portion where the gallium nitride layer 40 and the gallium nitride rods 30 meet, and the etching follows along the semi-polar face that is chemically most unstable.

Also, the first etching process in the present embodiment may be omitted. That is, the mask pattern may be removed through the etching that uses KOH, which is the second etching, and the gallium nitride rods may be consecutively removed.

The gallium nitride substrate 100 may be prepared through the process described above. A first face 110 of the gallium nitride substrate 100 thus prepared may be a relatively flat surface and may be a Ga-polar face according to the result of growth. Also, the first face 110 and a second face 120 that faces the first face 110 may be an N-polar face according to the result of growth. Protrusions 130 having a protruding shape are formed on the second face 120, and the protrusions 130 are formed by etching of the gallium nitride rods, where some of gallium nitride rod components remain in the protrusions 130. Also, a surface of the protrusions 130 opened according to the progress of etching is a semi-polar face.

Also, despite the second etching process, a separate substrate for growth may be used as a substrate for growth for crystal growth without damages in the following process.

The first face 110 of the gallium nitride substrate 100 formed according to the present embodiment is formed as a Ga-polar face of a flat surface; the second face 120 facing the first face 110 is an N-polar face; and the protrusions 130 are formed on the second face 120. A surface of the protrusions 130 is a semi-polar face. Since growth of crystals may be easily performed on the semi-polar face, growth of a thin layer may be enabled through the Ga-polar face and the semi-polar face. Therefore, the gallium nitride substrate 100 thus formed has a structure that allows double-sided growth.

Also, the protrusions 130 of the gallium nitride substrate 100 formed in the present embodiment are the result remained after partial etching of the gallium nitride substrate 100. Thus, the protrusions 130 should be understood as being served as nuclei of growth that forms the first face 110 and the second face 120.

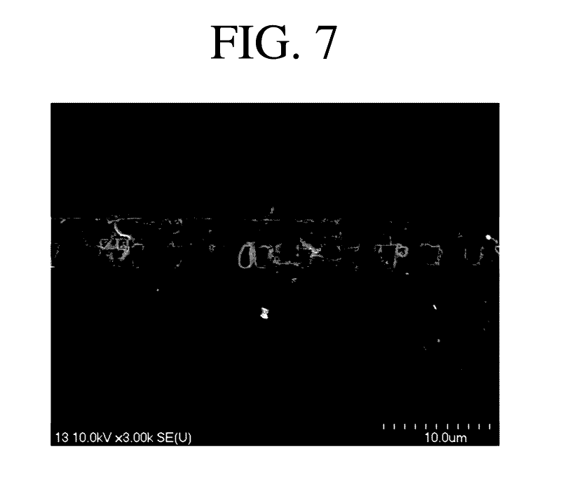

FIG. 7 is an image that shows a gallium nitride layer formed on a gallium nitride rod according to an embodiment of the present invention.

Referring to FIG. 7, a substrate for growth is a gallium nitride monocrystal. Also, mask patterns of a silicon oxide material are formed on the substrate for growth that includes a gallium nitride. An interval distance between the mask patterns ranges from 10 um to 15 um and has an under-cut shape that has an interval distance at lower parts greater than an interval distance at upper parts.

Also, gallium nitride rods are formed in gaps between the mask patterns. The gallium nitride rods are formed by introduction of precursors of gallium and nitrogen at a pressure of 30 torr by using H2 carriers. TMGa, as a gallium precursor, is introduced at a flow rate of 100 sccm, and NH3, as a nitrogen precursor, is introduced at a flow rate of 8000 sccm. A deposition time is set as 40 minutes.

Then, a gallium nitride layer is formed based on the gallium nitride rods. The gallium nitride layer is formed by introduction of precursors of gallium and nitrogen at a pressure of 100 torr by using a H2 carrier gas. TMGa, as a gallium precursor, is introduced at a flow rate of 100 sccm, and NH3, as a nitrogen precursor, is introduced at a flow rate of 8000 sccm. A deposition time is set as 20 minutes.

Also, a primary etching process is performed by using a HF solution. Through the primary etching process, a mask pattern is removed, and etching holes are formed.

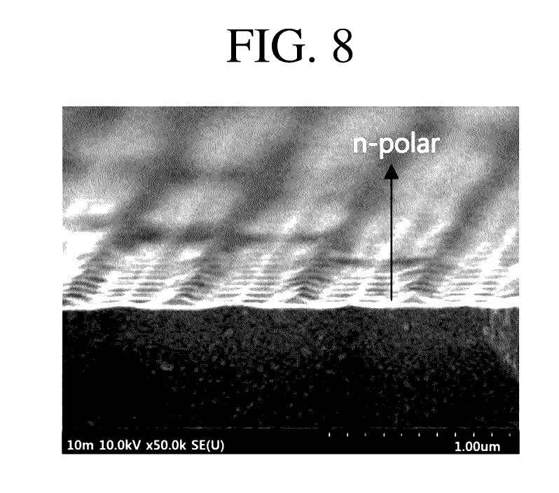

FIG. 8 is an image that shows the gallium nitride substrate according to an embodiment of the present invention.

Referring to FIG. 8, etching is performed on gallium nitride rods thus formed in an embodiment of FIG. 7 by introducing a KOH solution to the gallium nitride rods. The gallium nitride rods are intensively etched at a portion meeting with the gallium nitride layer, and a surface of the gallium nitride rods is formed as a semi-polar face. Also, the gallium nitride layer formed on the mask patterns of an embodiment of FIG. 7 becomes an N-polar face.

### Second Embodiment

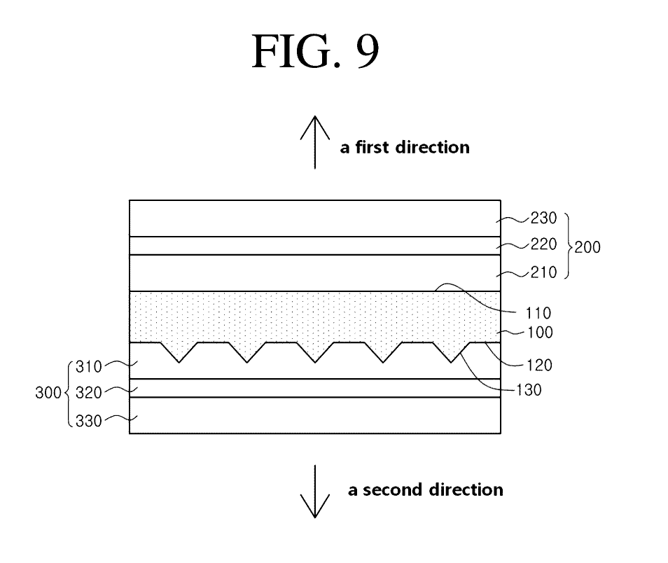

FIG. 9 is a cross-sectional view of a double-sided light-emitting diode according to another embodiment of the present invention.

Referring to FIG. 9, a double-sided light-emitting diode according to the present embodiment has a first light emitting body 200 formed in a first direction on a gallium nitride substrate 100 and a second light-emitting body 300 formed in a second direction that is opposite to the first direction, wherein the first light-emitting body 200 and the second light-emitting body 300 are formed based on the gallium nitride substrate 100.

The gallium nitride substrate 100 has a first face 110, a second face 120, and protrusions 130. The first face 110 is a Ga-polar face, the second face 120 is an N-polar face, and a surface of the protrusions 130 is formed as a semi-polar face. Also, the protrusions 130 are formed on the second face 120.

The first light-emitting body 200 is formed on the first face 110 of the gallium nitride substrate 100. The first light-emitting body 200 includes a first n-type semiconductor layer 210, a first active layer 220, and a first p-type semiconductor layer 230 that are sequentially stacked in a first direction. The first light-emitting body 200 uses a gallium nitride as a ground material. For example, the first light-emitting body 200 may form light of blue, red, or green color. For a blue light-emitting operation, a barrier layer of the first active layer 220 may include GaN, and a well layer may include InGaN. Also, for a green light-emitting operation, the first active layer 220 may use InGaN, AlGaN, or AlInGaN as a well layer and GaN as a barrier layer. That is, the first active layer 220 may be formed by formation of a well layer and a barrier layer as commonly known in the art to emit light of color.

Also, the first n-type semiconductor layer 210 and the first p-type semiconductor layer 230 may be formed according to a general preparation process of a light-emitting diode.

In particular, since the first face 110 of the gallium nitride substrate 100 is a Ga-polar face, the first face 110 is formed with the same mechanism with growth of a new gallium nitride semiconductor layer on a gallium nitride semiconductor layer. Growth of crystals on the Ga-polar face occurs smoothly, and thus formation of the first n-type semiconductor layer 210 may be easily performed.

Also, the light-emitting body 300 is formed in the second direction of the gallium nitride substrate 100. The second light-emitting body 300 growing in the second direction is formed by using the protrusions 130 of the gallium nitride substrate 100 as nuclei of growth. Growth through a MOCVD process is not smooth on the N-polar face that is distributed on the second face 120 of the gallium nitride substrate 100. However, a side surface of the protrusions 130 formed on the second face 120 is a semi-polar face, and growth dominantly occurs through the semi-polar face. Therefore, the second light-emitting body 300 grown from the semi-polar face includes a second n-type semiconductor layer 310, a second active layer 320, and a second p-type semiconductor layer 330 that are sequentially formed.

The second light-emitting body 300 thus formed may form light of various color. For example, light of blue, green, or red color may be formed. This may be selected by those of ordinary skill in the art.

However, in the present embodiment, the second n-type semiconductor layer 310 included in the second light-emitting body 300 may be formed based on the protrusions 130 that are formed with the semi-polar face of the gallium nitride substrate 100. Also, the second n-type semiconductor layer 310 may be formed by using an ELOG process, in which side surface growth is dominant The second active layer 320 and the second p-type semiconductor layer 330 may be formed by using a general MOCVD process after forming the second n-type semiconductor layer 310.

Therefore, two light-emitting bodies 200 and 300 are formed on two sides of the gallium nitride substrate 100. The light-emitting body formed on the first face 110 may form light of first color, and the light-emitting body formed on the second face 120 may form light of second color. The light of the first color and the light of the second color may be identical to or different from each other.

When the first color and the second color are different from each other, light of various colors may be formed by the light of different colors. Also, when the first color and the second color are identical to each other, a high brightness compared to the same substrate surface area may be obtained. In particular, when light of the first color and the second color is blue light, white light having a high brightness may be formed.

Also, a double-sided light-emitting diode may be formed by using various methods.

For example, the second light-emitting body 300 may be formed by forming the first light-emitting body 200 on the first face 110 of the gallium nitride substrate 100, placing the second face 120 facing the first face 110 to face upward, and using a general MOCVD process on the second face 120 or the protrusions 130. Further, a light-emitting body may be first formed on the second face 120 or the protrusions 130, and then another light-emitting body may be formed on the first face 110.

According to the present embodiment, a gallium nitride substrate having the first face has a Ga-polar face, the second face has an N-polar face, and the protrusions that are formed on the second face and have a semi-polar face may be obtained. The gallium nitride substrate is a semiconductor material and thus heat generated from the light-emitting body may be easily released to the outside. Also, even when gallium nitride-based light-emitting bodies are not formed on the top of the gallium nitride substrate, orientation and lattice constants of crystals are substantially the same, and thus a monocrystal of high quality may be obtained. Therefore, light-emitting bodies of high quality may be obtained.

Also, the light-emitting bodies may be formed on both surfaces of the gallium nitride substrate thus formed, and when the light-emitting bodies are used, a light-emitting diode that may realize various colors and a high brightness may be obtained.

What is claimed is:

1. A gallium nitride substrate comprising:
a first face that comprises a Ga-polar face having gallium atoms arranged on a surface thereof;
a second face that faces the first face and comprises an N-polar face having nitrogen atoms arranged on a surface thereof; and
protrusions that are formed on the second face and have a protruding surface, which is a semi-polar surface.

2. The gallium nitride substrate of claim 1, wherein the gallium atoms and the nitrogen atoms appear on a surface through the semi-polar surface.

3. The gallium nitride substrate of claim 1, wherein an interval distance between the protrusions adjacent to each other is constant.

4. The gallium nitride substrate of claim 1, wherein the protrusions function as nuclei for growth to form the first face and the second face.

5. A method of preparing a gallium nitride substrate, the method comprising:
forming mask patterns and gallium nitride rods that reclaim gaps between the mask patterns on a substrate for growth;
covering the mask patterns by having the gallium nitride rods as nuclei for growth to form a gallium nitride layer;
removing the covered mask patterns; and
etching the gallium nitride rods by providing an etchant to etched holes formed by the removing of the mask patterns to form protrusions having some of the gallium nitride rods remained on the gallium nitride layer.

6. The method of claim 5, wherein the forming of the mask patterns and gallium nitride rods on a substrate for growth comprises:
forming the mask patterns on the substrate for growth; and
growing the gallium nitride rods that reclaim the gaps between the mask patterns.

7. The method of claim 5, wherein side surfaces of the gallium nitride rods have semi-polar faces.

8. The method of claim 5, wherein the protrusions have semi-polar faces.

9. The method of claim 5, wherein the first face at an upper part of the gallium nitride is a Ga-polar face, and the second face that faces the first face and contacts the mast patterns is a N-polar face.

10. The method of claim 5, wherein the etchant is a KOH solution, and a concentration of the KOH solution ranges from about 1 M to about 5 M, and a temperature of the etchant ranges from about 60° C. to about 120° C.

11. A double-sided light-emitting diode comprising:
a gallium nitride substrate formed of a gallium nitride material;
a first light-emitting body that has been grown in a first direction from the gallium nitride substrate; and
a second light-emitting body that has been grown in a second direction, which is opposite to the first direction, from the gallium nitride substrate.

12. The double-sided light-emitting diode of claim 11, wherein the gallium nitride substrate comprises:
a first face that is configured to have a Ga-polar face having gallium atoms arranged on a surface thereof;
a second face that is configured to have an N-polar face having nitrogen atoms arranged on a surface thereof; and
protrusions that are formed on the second face and have a protruding surface, which is a semi-polar surface.

13. The double-sided light-emitting diode of claim 12, wherein the first light-emitting body is formed on the first face which forms light of a first color, and the second light-emitting body is formed on the second face which forms light of a second color.
